(19) United States
(12) Patent Application Publication
(10) Pub. No.: US 2006/0286403 A1
(43) Pub. Date: Dec. 21, 2006

(54) Organic light emitting diode and method of fabricating the same

(75) Inventor: Chung-Chun Lee, Lunbei Township (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: AU Optronics Corp.

(21) Appl. No.: 11/199,307

(22) Filed: Aug. 8, 2005

(30) Foreign Application Priority Data
Jun. 20, 2005 (TW) 94120413

(51) Int. Cl. H01L 51/54; H05B 33/12

(52) U.S. Cl. 428/690; 428/917; 313/504; 313/506; 257/E51.049; 427/66

(57) ABSTRACT

An organic light emitting diode is provided. The organic light emitting diode includes a cathode, an anode, and an electron-transporting layer disposed therebetween, wherein the electron-transporting layer comprises a fluorene derivative having electron/hole mobility exceeding 10-7 cm2v-1s-1 and a metal-containing material. The invention also provides a method of fabricating the organic light emitting diode.

### BACKGROUND

The present invention relates to an organic electroluminescent device, and more specifically, to an organic light emitting diode.

Organic electroluminescent devices have great potential in the flat panel display industry due to their high illumination, light weight, self-illumination, low power consumption, simple fabrication, rapid response time, wide viewing angle, and no backlight requirement.

When an external electric field is applied to an organic electroluminescent device, carriers such as electrons and holes are injected respectively into an organic electroluminescent layer and then recombined to form excitons. Energy is further transferred from excitons to luminescent molecules by continuously applying an electric field. Finally, luminescent molecules emit light converted from energy. A common organic electroluminescent device structure comprises an anode, a hole-transporting layer, an emitting layer, an electron-transport layer, and a cathode. A complex organic electroluminescent device, however, may further comprise a hole-injection layer interposed between an anode and a hole-transporting layer, an electron-injection layer interposed between a cathode and an electron-transporting layer, and/or a hole-blocking layer interposed between an emitting layer and an electron-transporting layer so as to improve injection efficiency of carriers, to reduce driven voltage, or to increase recombination thereof.

Conventional Alq₃ electron-transporting layers may easily produce Alq₃⁺ when considerable quantities of holes exist, resulting in deterioration of product lifetime. Additionally, the electron mobility of Alq₃ is inferior to about 10⁻⁷ cm²v⁻¹s⁻¹, causing low electron-transporting capability and luminescent efficiency. Therefore, it is desirable to develop a new electron-transporting material to replace the conventional Alq₃.

In one aspect of the present invention, there is provided an organic light emitting diode comprising a cathode, an anode, and an electron-transporting layer disposed therebetween, wherein the electron-transporting layer comprises a fluorene derivative having electron/hole mobility exceeding 10⁻⁷ cm²v⁻¹s⁻¹ and a metal-containing material.

In another aspect of the present invention, there is also provided a method of fabricating an organic light emitting diode. A substrate is provided and an electrode disposed thereon. The disclosed electron-transporting layer is disposed on the electrode. Another electrode is disposed on the electron-transporting layer.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1 is a cross section of an organic light emitting diode of the invention; and

FIG. 2 is a lifetime comparison among various organic light emitting diodes.

### DETAILED DESCRIPTION

The present invention provides an organic light emitting diode comprising a cathode, an anode, and an electron-transporting layer disposed therebetween. The electron-transporting layer comprises a fluorene derivative having electron/hole mobility exceeding 10⁻⁷ cm²v⁻¹s⁻¹ and a metal-containing material.

The electron-transporting layer has a thickness of about 50 Å to 5000 Å. The fluorene derivative and the metal-containing material have a volume ratio of about 0.5:99.5 to about 99.5:0.5, preferably about 80:20 to about 50:50. The fluorene derivative may comprise fluorene oligomers.

The metal-containing material may be metal, metal oxide, inorganic metal salt, organic metal salt, or a combination thereof. The metal may comprise alkali metal, alkaline metal, or a combination thereof. The metal oxide, inorganic metal salt, and organic metal salt, have a cation comprising Li⁺, Na⁺, K⁺, Cs⁺, Mg²⁺, Ca²⁺, Ba²⁺, or a combination thereof. The metal oxide and inorganic metal salt have an anion comprising O²⁻, F⁻, Cl⁻, Br⁻, I⁻, CO₃²⁻, NO₃⁻, CH₃COO⁻, or a combination thereof. The organic metal salt has an anion comprising aliphatic or aromatic organic anion having fewer carbon atoms than 30.

The invention provides a new electron-transporting layer comprising a fluorene derivative having electron/hole mobility exceeding 10⁻⁷ cm²v⁻¹s⁻¹ and a metal-containing material to greatly improve electrical performance and lifetime of an organic electroluminescent device.

The invention provides a fluorene derivative capable of stabilizing electrons and holes to replace a conventional Alq₃ compound in an electron-transporting layer to avoid production of Alq₃⁺, effectively prolonging device lifetime. The operating voltage of a device can also be reduced by adding the described fluorene derivative and/or by doping the metal-containing material. Thus, capability of electron injection is significantly increased and luminescent efficiency is improved.

The organic light-emitting diode provided by the invention further comprises a hole-injection layer, a hole-transporting layer, an emitting layer, or an electron-injection layer. The hole-injection layer comprises a polymer containing F, C, and H, porphyrin derivative, or p-doped diamine derivative. The porphyrin derivative may comprise metallophthalocyanine derivative, such as copper phthalocyanine.

The hole-transporting layer may comprise diamine derivative, such as N,N′-bis(1-naphyl)-N,N′-diphenyl-1,1′-biphenyl-4,4′-diamine (NPB), N,N′-diphenyl-N,N′-bis(3-methylphenyl)-(1,1′-biphenyl)-4,4′-diamine (TPD), or 2T-NATA. The hole-transporting layer has a thickness of about 50˜5000 Å. The emitting layer may comprise a single layer or multiple layers comprising fluorescent emitter, phosphorescent emitter, or a combination thereof and has a thickness of about 50 Å to 2000 Å. The electron-injection layer may comprise alkali halide, alkaline halide, alkali oxide, metal carbonate, or metal acetate such as LiF, CsF, NaF, CaF₂, Li₂O, Cs₂O, Na₂O, Li₂CO₃, Cs₂CO₃, Na₂CO₃, or CH₃COOCs, and has a thickness of about 5˜500 Å.

At least one of the cathode and anode is a transparent electrode, that is, the cathode and the anode may be the same or different materials, and they may comprise a single layer or multiple layers comprising metal, transparent oxide, or a combination thereof. The metal may be Al, Ca, Ag, Ni, Cr, Ti, Mg, or alloy thereof. The transparent oxide may comprise ITO, AZO, ZnO, InN, or SnO₂.

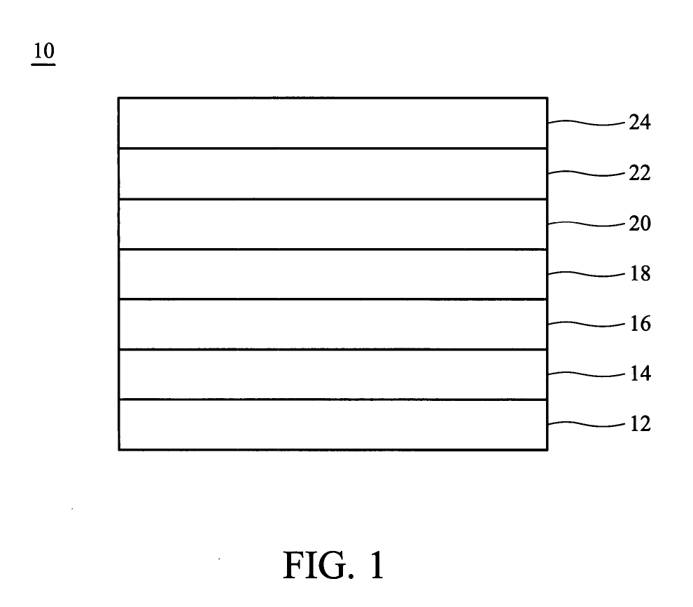

An organic light-emitting diode provided by the invention is disclosed in FIG. 1. The organic light-emitting diode 10 comprises an anode 12, a hole-injection layer 14, a hole-transporting layer 16, an emitting layer 18, an electron-transporting layer 20 comprising a fluorene derivative and a metal-containing material, an electron-injection layer 22, and a cathode 24.

Referring to FIG. 1, a method of fabricating an organic light emitting diode is provided. First, an anode 12 is provided. Next, a hole-injection layer 14, a hole-transporting layer 16, an emitting layer 18, an electron-transporting layer 20, an electron-injection layer 22, and a cathode 24 are evaporated on the anode 12 in order. Finally, the diode is packaged to form an organic light emitting device.

### EXAMPLES

### Comparative Example 1

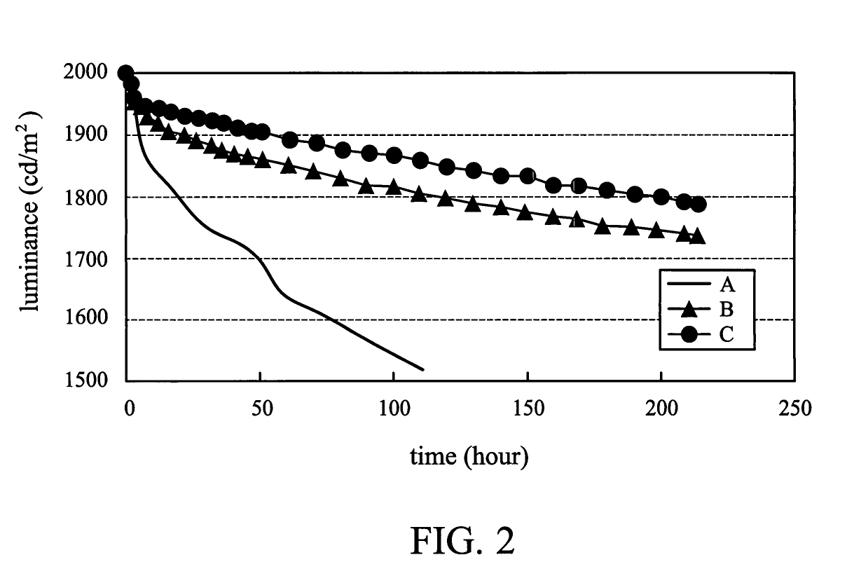

Referring to FIG. 1, a method of fabricating an organic light emitting diode (device A) is disclosed in the following. First, an ITO anode 12 was provided on a substrate. The anode 12 was then treated with UV ozone. Next, copper phthalocyanine was evaporated on the ITO anode 12 to form a hole-injection layer 14. Next, NPB was evaporated on the hole-injection layer 14 to form a hole-transporting layer 16. A green emitting layer 18 was then evaporated on the hole-transporting layer 16. Next, tris(8-hydroxyquinoline)aluminum(III) (Alq₃) was evaporated on the emitting layer 18 to form an electron-transporting layer 20. Next, LiF was evaporated on the electron-transporting layer 20 to form an electron-injection layer 22. Finally, Al was evaporated on the electron-injection layer 22 to form a cathode 24. After packaging, the organic light emitting diode 10 (device A) was formed. The lifetime curve A of the device A is shown in FIG. 2.

### Example 1

Referring to FIG. 1, a method of fabricating an organic light-emitting diode (device B) of the invention is provided. First, an ITO anode 12 was provided on a substrate. The anode 12 was then treated with UV ozone. Next, copper phthalocyanine was evaporated on the ITO anode 12 to form a hole-injection layer 14. Next, NPB was evaporated on the hole-injection layer 14 to form a hole-transporting layer 16. A green emitting layer 18 was then evaporated on the hole-transporting layer 16. Next, ter(9,9-di-p-tolylfluorene) and CsF were co-evaporated on the emitting layer 18 to form an electron-transporting layer 20. The volume ratio of ter(9,9-di-p-tolylfluorene) and CsF was 0.8:0.2. Next, LiF was evaporated on the electron-transporting layer 20 to form an electron-injection layer 22. Finally, Al was evaporated on the electron-injection layer 22 to form a cathode 24. After packaging, the organic light emitting diode 10 (device B) was formed. The lifetime curve B of the device B is shown in FIG. 2.

### Example 2

Referring to FIG. 1, another method of fabricating an organic light-emitting diode (device C) of the invention is provided. First, an ITO anode 12 was provided on a substrate. The anode 12 was then treated with UV ozone. Next, copper phthalocyanine was evaporated on the ITO anode 12 to form a hole-injection layer 14. Next, NPB was evaporated on the hole-injection layer 14 to form a hole-transporting layer 16. A green emitting layer 18 was then evaporated on the hole-transporting layer 16. Next, ter(9,9-di-p-tolylfluorene) and CsF were co-evaporated on the emitting layer 18 to form an electron-transporting layer 20. The volume ratio of ter(9,9-di-p-tolylfluorene) and CsF was 0.6:0.4. Next, LiF was evaporated on the electron-transporting layer 20 to form an electron-injection layer 22. Finally, Al was evaporated on the electron-injection layer 22 to form a cathode 24. After packaging, the organic light emitting diode 10 (device C) was formed. The lifetime curve C of the device C is shown in FIG. 2.

Compared to curve A˜C, the device B and C provided by the invention have slower decrease rate in illumination than the related device A, having longer lifetime.

The performance of the devices is cited in TABLE 1.

TABLE 1

| | Operating | Efficiency | Efficiency |
|---|---|---|---|
| device | voltage (V) | (cd/A) | (lm/W) |
| A | 6.4 | 9.8 | 4.8 |
| B | 5.6 | 12.5 | 7.1 |
| C | 5.0 | 11.6 | 7.3 |

The results of Table 1 indicate that the devices B and C provided by the invention have lower operating voltage and higher luminescent efficiency than the related device A at 2000 nits.

While the present invention has been described by way of example and in terms of preferred embodiments, it is to be understood that the present invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An organic light emitting diode, comprising:
a cathode;
an anode; and
an electron-transporting layer disposed between the cathode and anode, wherein the electron-transporting layer comprises a fluorene derivative having electron/hole mobility exceeding 10-7 cm2v-1s-1 and a metal-containing material.

2. The organic light emitting diode as claimed in claim 1, wherein the electron-transporting layer has a thickness of about 50 Å to about 5000 Å.

3. The organic light emitting diode as claimed in claim 1, wherein the fluorene derivative and the metal-containing material have a volume ratio of about 0.5:99.5 to about 99.5:0.5.

4. The organic light emitting diode as claimed in claim 1, wherein the fluorene derivative and the metal-containing material have a volume ratio of about 80:20 to about 50:50.

5. The organic light emitting diode as claimed in claim 1, wherein the fluorene derivative comprises fluorene oligomer.

6. The organic light emitting diode as claimed in claim 1, wherein the metal-containing material is selected from the group consisting of metal, metal oxide, organic metal salt, and a combination thereof.

7. The organic light emitting diode as claimed in claim 6, wherein the metal is selected from the group consisting of alkali metal, alkaline-earth metal, and a combination thereof.

8. The organic light emitting diode as claimed in claim 6, wherein the metal oxide has a cation selected from the group consisting of Li+, Na+, K⁺, Cs+, Mg2+, Ca2+, Ba2+, and a combination thereof.

9. The organic light emitting diode as claimed in claim 6, wherein the metal oxide has an anion selected from the group consisting of O₂—, F—, Cl—, Br—, I—, CO32-, NO3—, CH3COO—, and a combination thereof.

10. The organic light emitting diode as claimed in claim 6, wherein the organic metal salt has a cation selected from the group consisting of Li+, Na+, K+, Cs+, Mg2+, Ca2+, Ba2+, and a combination thereof.

11. The organic light emitting diode as claimed in claim 6, wherein the organic metal salt has an anion comprising aliphatic or aromatic organic anion having carbon atoms less than 30.

12. The organic light emitting diode as claimed in claim 1, further comprising an emitting layer disposed between the anode and the electron-transporting layer.

13. The organic light emitting diode as claimed in claim 12, wherein the emitting layer comprises one or more layers comprising fluorescent emitter, phosphorescent emitter, or a combination thereof.

14. The organic light emitting diode as claimed in claim 1, wherein at least one of the cathode and anode is a transparent electrode

15. The organic light emitting diode as claimed in claim 14, wherein the cathode and anode comprise one or more layers comprising metal, transparent oxide, or a combination thereof.

16. The organic light emitting diode as claimed in claim 1, wherein the cathode and anode are made of the same material.

17. The organic light emitting diode as claimed in claim 12, further comprising at least one of a hole-injection layer and a hole-transporting layer disposed between the anode and the emitting layer.

18. The organic light emitting diode as claimed in claim 17, wherein the hole-injection layer comprises polymers containing F, C, and H, porphyrin derivatives, or p-doped diamine derivatives.

19. The organic light emitting diode as claimed in claim 17, wherein the hole-transporting layer comprises diamine derivatives.

20. The organic light emitting diode as claimed in claim 1, further comprising an electron-injection layer disposed between the cathode and the electron-transporting layer.

21. The organic light emitting diode as claimed in claim 20, wherein the electron-injection layer comprises alkali halide, alkaline halide, alkali oxide, metal carbonate, or a combination thereof.

22. A method of fabricating an organic light emitting diode, comprising:
providing a substrate;
forming an anode on the substrate;
forming an electron-transporting layer of claim 1 on the anode; and
forming a cathode on the electron-transporting layer.

23. The method as claimed in claim 22, further comprising disposing an emitting layer between the anode and the electron-transporting layer.
